(19) United States
(12) Patent Application Publication
(10) Pub. No.: US 2009/0141409 A1
(43) Pub. Date: Jun. 4, 2009

(54) SPIN FILTER SPINTRONIC DEVICES

(76) Inventors: Tiffany S. Santos, Downers Grove, IL (US); Jagadeesh S. Moodera, Somerville, MA (US)

Correspondence Address: GAUTHIER & CONNORS, LLP, 225 FRANKLIN STREET, SUITE 2300, BOSTON, MA, 02110, US

(21) Appl. No.: 11/949,208

(22) Filed: Dec. 3, 2007

(51) Int. Cl. G11B 5/127

(52) U.S. Cl. 360/324.2

(57) ABSTRACT

A spin filter transistor having a semiconductor structure. A spin injector including a first spin filter tunnel barrier is positioned on the semiconductor structure. A spin detector including a second spin filter tunnel barrier is positioned on the semiconductor. Highly polarized spins injected from the spin injector are transported through the semiconductor structure, and are detected at the spin detector. The magnitude of the spin current depends on the relative magnetic alignment of the first spin filter tunnel barrier and the second spin filter tunnel barrier.

### BACKGROUND OF THE INVENTION

The invention is related to the field of spin polarized tunneling, and in particular to using spins filters to form spintronic devices.

A spin filter has the unique capability to generate an electron spin-polarized current, with a high degree of polarization reaching 100%. Thus, a spin filter has great application potential in spin electronic (or “spintronic”) devices, including magnetoresistive tunnel junctions, spin transistors (spin-FETs), and spin light emitting diodes (spin-LEDs). The goal in the active field of spintronics is to store and transport information in the electron spin, with the application of making magnetic field sensors, read heads in hard drives, high-density, non-volatile memory, and high-speed data processing. The phenomenon of tunneling is a direct consequence of quantum mechanics. Although the concept existed in the late 1920s, the field developed rapidly since the classic experiments of the tunnel current between a superconductor and a normal metal through a thin Al₂O₃ barrier. Immediately following, there was huge activity in experimental and theoretical research in tunneling, starting with superconductivity and later encompassing a broader field.

The spin splitting of the superconducting density of states (DOS) in Al led to the phenomenal first spin-polarized tunneling (SPT) experiment: the superconducting Al acting as a spin detector for the tunneling electrons from a ferromagnet (FM) counter-electrode in Al/Al₂O₃/FM. Conservation of electron spin in the tunneling process is important in the observation of spin polarization. Several excellent reviews have been written on the subject over the years. The spin polarization P is defined as

P=[N_{-(E}_{_{F}}₎−N_{-(E}_{_{F}}₎]/[N_{-(E}_{_{F}}₎+N_{-(E}_{_{F}}₎] EQ. 1

where N_{↑(E}_{_{F}}₎ and N_{↓(E}_{_{F}}₎ are the number of majority spin and minority spin electrons in the tunneling current near the Fermi energy E_{F}.

### SUMMARY OF THE INVENTION

According to one aspect of the invention, there is provided a spin filter transistor structure. The spin filter transistor includes a semiconductor structure. A spin injector including a first spin filter tunnel barrier is positioned on the semiconductor structure. A spin detector including a second spin filter tunnel barrier is positioned on the semiconductor. Highly polarized spins injected from the spin injector are transported through the semiconductor structure, and are detected at the spin detector. The magnitude of the spin current depends on the relative magnetic alignment of the first spin filter tunnel barrier and the second spin filter tunnel barrier.

According to another aspect of the invention, there is provided a method of operating a spin filter transistor. The method includes providing a semiconductor structure. Also, the method includes positioning a spin injector including a first spin filter tunnel barrier on the semiconductor structure. A spin detector including a second spin filter tunnel barrier is positioned on the semiconductor. Furthermore, the method includes injecting highly polarized spins from the spin injector that are transported through the semiconductor structure, and are detected at the spin detector. The magnitude of the spin current depends on the relative magnetic alignment of the first spin filter tunnel barrier and the second spin filter tunnel barrier.

### BRIEF DESCRIPTION OF THE DRAWINGS

FIG. 1 is a schematic diagram of a tunneling spin-filter effect in a metal/EuO spin filter/metal tunnel junction; and

FIG. 2 is a schematic diagram of a spin transport transistor in accordance with the invention.

### DETAILED DESCRIPTION OF THE INVENTION

The invention uses a spin filter to inject and detect polarized spins in spintronic device structures at room temperature. In particular, the spin filtering phenomenon allows one to obtain highly spin-polarized charge carriers using magnetic tunnel barriers, even when nonmagnetic electrodes are used. A spin filter is a semiconducting or insulating, magnetic tunnel barrier that selectively allows only one spin orientation (either spin-up or spin-down) to tunnel, thus generating a spin-polarized current. The exponential dependence of tunnel current on the tunnel barrier height is operative here. The magnetic, semiconducting europium chalcogenide compounds have strikingly demonstrated this effect. The possibility of employing ferrites and garnets opens the potential for display of this phenomenon at room temperature, which can be expected to lead to huge progress in spin injection and detection in semiconductors.

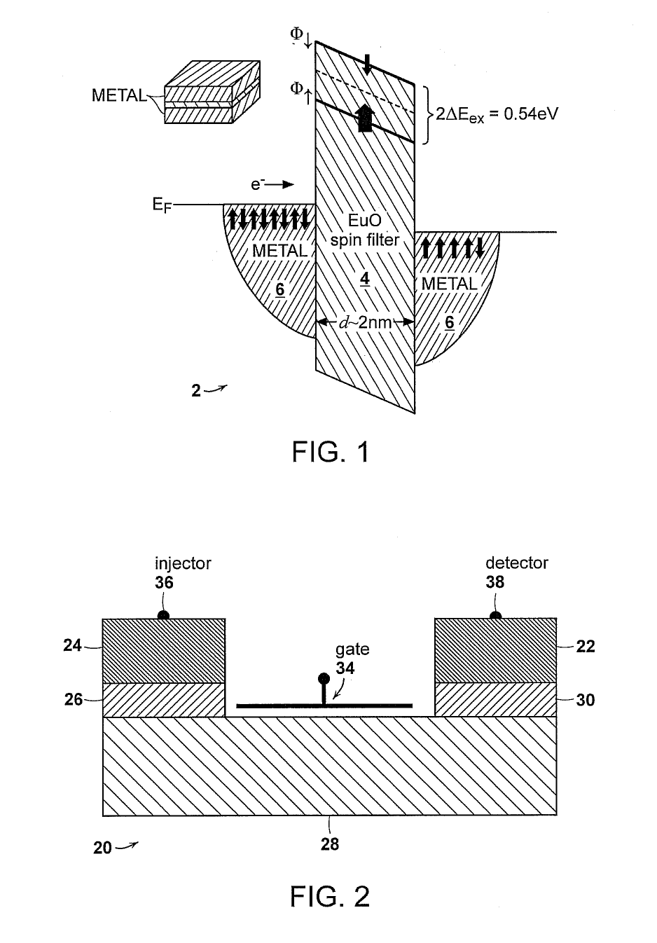

FIG. 1 shows a schematic diagram of the tunneling spin-filter effect in a metal/EuO spin filter/metal tunnel junction 2. Electrons with randomly oriented spins tunnel from the Fermi level of the nonmagnetic metal 6 through the EuO spin-filter barrier 4. The spin-split conduction band of ferromagnetic EuO 4 creates a lower barrier height for spin-up electrons (Φ↑) and higher barrier height for spin-down electrons (Φ↓), giving rise to a highly spin-polarized current.

In contrast to conventional SPT devices using a ferromagnetic metal as the source for spin-polarized electrons, in the novel approach of spin-filter tunneling a ferri- or ferromagnetic tunnel barrier is used to generate a polarized current, called the spin-filter effect, shown schematically in FIG. 1. In the magnetically ordered state, exchange splitting of the conduction band creates two different tunnel barrier heights, a lower one for spin-up electrons (Φ↑) and a higher one for spin-down electrons (Φ↓). In general, during the tunneling process Spin is conserved. Therefore, for a given barrier thickness d, the tunnel current density J depends exponentially on the corresponding barrier heights:

J_{↑(↓)}∝exp(−Φ_{↑(↓)}^{1/2}d) EQ. 2

Therefore, even with a modest difference in barrier heights, the tunnel probability for spin-up electrons is much greater than that for spin-down electrons, resulting in spin polarization (P) of the tunnel current:

$$P = \frac{{J}_{↑} - {J}_{↓}}{{J}_{↑} + {J}_{↓}} \qquad EQ . 3$$

The magnitude of exchange splitting (2ΔEₑₓ) for spin-filter materials such as the europium chalcogenides is substantial; for example, the largest is 0.54 eV for EuO, which could completely filter out spin-down electrons, leading to P=100%. In the europium chalcogenides, the spin-up conduction band is lower in energy relative to the spin-down band, as described above. However, in other spin filter materials, such as the ferrites, it is possible that the spin-down band is lower in energy, giving rise to negative spin polarization.

The spin-filter effect has been well observed in europium chalcogenide tunnel barriers EuS and EuSe and more recently with EuO. EuS barriers have shown P as high as 85% even at zero applied magnetic fields. Interestingly, in the case of EuSe, which is an antiferromagnet that becomes ferromagnetic in a small applied magnetic field, field-dependent exchange splitting of the conduction band appears. Due to this, the resulting P turns out to be field dependent in the case of EuSe barriers: P=0 in zero field and increases with applied field, reaching nearly 100% at 1 T. EuS and EuSe have magnetic ordering temperatures of 16.6 K (ferromagnetic) and 4.6 K (antiferromagnetic), respectively, and thus only filter spins at temperatures in the liquid helium temperature range.

With a higher T_{C}, 69.3 K, and greater exchange splitting, EuO holds promise to reach greater spin-filter efficiency at higher temperatures. There has been some progress recently with other promising candidates, namely ferrites and perovskites. Ferrites such as ferrimagnetic CoFe₂O₄ and NiFe₂O₄ have magnetic ordering temperatures well above room temperature and thus could potentially filter spins at a convenient temperature range. Among the perovskites, some degree of spin filtering has been observed using insulating, ferromagnetic BiMnO₃ with a T_{C} of 105 K.

FIG. 2 is a schematic diagram of a spin transport transistor 20 in accordance with the invention. The spin transport transistor 20 includes a spin injector 36 being comprised of the metallic electrode 24 and the spin filter tunnel barrier 26. A spin detector 38 is comprised of a second metallic electrode 22 and a second spin filter tunnel barrier 30. Highly polarized spins are injected from the spin injector 36, are transported through a semiconductor 28, and are detected at the spin detector. Both the spin injector 36 and spin detector 38 are positioned on the semiconductor 28. The magnitude of the spin current depends on the relative magnetic alignment of the spin filter 26 and the spin filter 30.

A gate 34 is the third electrode of the transistor 20, which functions to control the magnitude of the spin current during transport in semiconductor 28. A voltage applied to gate 34 creates an effective magnetic field that causes the spins to precess during transport, which changes the relative alignment of the spins to the injector 36 and detector 38, and thus alters the magnitude of the spin current. The gate is comprised a metallic electrode, separated from the semiconductor 28 by an insulating, dielectric layer, such as Al₂O₃ or SiO₂.

The metallic electrodes 24 and 22 can be comprised of nonmagnetic metal, such as Cu, Al, Au, Ag or ferromagnetic metal, such as Fe, Co, Ni and their alloys. Moreover, the semiconductor 28 can include GaAs, InGaAs, AlGaAs, GaN, Si or SiGe. The semiconductor 28 can also include a 2-dimensional electron gas (2DEG), which is a high mobility carrier transport layer located just below the top surface of semiconductor 28.

Although the present invention has been shown and described with respect to several preferred embodiments thereof, various changes, omissions and additions to the form and detail thereof, may be made therein, without departing from the spirit and scope of the invention.

What is claimed is:

1. A spin filter transistor structure comprising:
a semiconductor structure;
a spin injector including a first spin filter tunnel barrier positioned on said semiconductor structure; and
a spin detector including a second spin filter tunnel barrier positioned on said semiconductor structure; wherein
highly polarized spins injected from the spin injector are transported through the semiconductor structure, and are detected at the spin detector, the magnitude of the spin current depends on the relative magnetic alignment of the first spin filter tunnel barrier and the second spin filter tunnel barrier.

2. The spin filter transistor structure of claim 1, wherein said spin injector comprises a first metallic electrode.

3. The spin filter transistor structure of claim 1, wherein said spin detector comprises a second metallic electrode.

4. The spin filter transistor structure of claim 2, wherein said first metallic electrode comprises nonmagnetic materials.

5. The spin filter transistor structure of claim 3, wherein said second metallic electrode comprises nonmagnetic materials.

6. The spin filter transistor structure of claim 2, wherein said first metallic electrode comprises ferromagnetic materials.

7. The spin filter transistor structure of claim 3, wherein said second metallic electrode comprises ferromagnetic materials.

8. The spin filter transistor structure of claim 1, wherein said semiconductor structure comprises GaAs, InGaAs, AlGaAs, GaN, Si or SiGe.

9. The spin filter transistor structure of claim 1, wherein said semiconductor structure comprises a 2-dimensional electron gas (2DEG).

10. The spin filter transistor structure of claim 1 further comprising a gate electrode positioned on said semiconductor structure.

11. The spin filter transistor structure of claim 4, wherein said nonmagnetic materials comprise Cu, Al, Au, or Ag.

12. The spin filter transistor structure of claim 5, wherein said nonmagnetic materials comprise Cu, Al, Au, or Ag.

13. The spin filter transistor structure of claim 6, wherein said ferromagnetic materials comprise Fe, Co, Ni and their alloys.

14. The spin filter transistor structure of claim 7, wherein said ferromagnetic materials comprise Fe, Co, Ni and their alloys.

15. A method of operating a spin filter transistor comprising:
providing a semiconductor structure;
positioning a spin injector including a first spin filter tunnel barrier on said semiconductor structure;
positioning a spin detector including a second spin filter tunnel barrier on said semiconductor; and
injecting highly polarized spins from the spin injector that are transported through the semiconductor structure, and are detected at the spin detector, the magnitude of the spin current depends on the relative magnetic alignment of the first spin filter tunnel barrier and the second spin filter tunnel barrier.

16. The method of claim 15, wherein said spin injector comprises a first metallic electrode.

17. The method of claim 15, wherein said spin detector comprises a second metallic electrode.

18. The method of claim 16, wherein said first metallic electrode comprises nonmagnetic materials.

19. The method of claim 17, wherein said second metallic electrode comprises nonmagnetic materials.

20. The method of claim 16, wherein said first metallic electrode comprises ferromagnetic materials.

21. The method of claim 17, wherein said second metallic electrode comprises ferromagnetic materials.

22. The method of claim 15, wherein said semiconductor structure comprises GaAs, InGaAs, AlGaAs, GaN, Si or SiGe.

23. The method of claim 15, wherein said semiconductor structure comprises a 2-dimensional electron gas (2DEG).

24. The method of claim 18, wherein said nonmagnetic materials comprise Cu, Al, Au, or Ag.

25. The method of claim 19, wherein said nonmagnetic materials comprise Cu, Al, Au, or Ag.

26. The method of claim 20, wherein said ferromagnetic materials comprise Fe, Co, Ni and their alloys.

27. The method of claim 21, wherein said ferromagnetic materials comprise Fe, Co, Ni and their alloys.

28. The method of claim 15 further comprising positioning a gate electrode on said semiconductor structure.
